(19) United States
(12) Patent Application Publication
(10) Pub. No.: US 2023/0334331 A1
(43) Pub. Date: Oct. 19, 2023

(54) MANAGEMENT APPARATUS, PROCESSING SYSTEM, MANAGEMENT METHOD, AND ARTICLE MANUFACTURING METHOD

(71) Applicant: CANON KABUSHIKI KAISHA, Tokyo (JP)

(72) Inventors: Ryo NAWATA, Tochigi (JP); Yuichiro MIKI, Kanagawa (JP)

(21) Appl. No.: 18/297,850

(22) Filed: Apr. 10, 2023

(30) Foreign Application Priority Data
Apr. 15, 2022 (JP) 2022-067816

(51) Int. Cl. G06N 3/092

(52) U.S. Cl. CPC G06N 3/092

(57) ABSTRACT

Provided is a management apparatus for managing a processing apparatus including a driver configured to drive a target object in regard to a plurality of drive axes, and a controller configured to control the driver using a neural network for which a parameter for outputting a manipulated variable to the target object is decided by reinforcement learning. The management apparatus includes a learning unit configured to decide the parameter of the neural network by reinforcement learning. The learning unit performs the reinforcement learning by evaluating a reward obtained from a control result of the target object by the controller, and relatively adjusts rewards regarding the respective drive axes in accordance with required precisions for the respective drive axes.

### BACKGROUND OF THE INVENTION

### Field of the Invention

The present invention relates to a management apparatus, a processing system, a management method, and an article manufacturing method.

### Description of the Related Art

For a control apparatus that controls a physical amount of a target object, a classic controller such as PID control has been widely used. In recent years, a control system constructed using machine learning (including reinforcement learning) is sometimes used in addition to control systems based on classic control theory and modern control theory. A control system that uses both a control system including no machine learning and a control system including machine learning may also be used. According to Japanese Patent Laid-Open No. 2019-71405, a feedback control apparatus that uses both a control system including no machine learning and a control system including machine learning is adopted to reduce, by the control system including machine learning, the control deviation of a target object that cannot be compensated completely only by the control system including no machine learning.

When a control system performs control regarding a plurality of drive axes, the required precisions of the respective drive axes may differ from each other. In this case, if feedback control is performed in regard to the respective drive axes by the method described in Japanese Patent Laid-Open No. 2019-71405, the control deviations of some drive axes may satisfy the required precisions, whereas those of some drive axes may not satisfy the required precisions. To satisfy the required precisions by all the drive axes, the control systems of the respective drive axes are designed in conformity with a drive axis whose required precision is strictest. In this case, however, the specifications become excessive for a drive axis whose required precision is not strict, and an unwanted calculation cost is generated disadvantageously in efficiency.

### SUMMARY OF THE INVENTION

The present invention provides a technique advantageous for efficiently performing control that satisfies the required precisions of respective drive axes at limited calculation cost.

The present invention in its one aspect provides a management apparatus for managing a processing apparatus including a driver configured to drive a target object in regard to a plurality of drive axes, and a controller configured to control the driver using a neural network for which a parameter for outputting a manipulated variable to the target object is decided by reinforcement learning, the management apparatus including a learning unit configured to decide the parameter of the neural network by reinforcement learning, wherein the learning unit performs the reinforcement learning by evaluating a reward obtained from a control result of the target object by the controller, and relatively adjusts rewards regarding the respective drive axes in accordance with required precisions for the respective drive axes.

Further features of the present invention will become apparent from the following description of exemplary embodiments (with reference to the attached drawings).

### BRIEF DESCRIPTION OF THE DRAWINGS

FIG. 1 is a block diagram showing an example of the configuration of a manufacturing system;

FIG. 2 is a view showing an example of the arrangement of a stage apparatus;

FIG. 3 is a block diagram showing an example of the arrangement of the control system of the stage apparatus;

FIG. 4 is a block diagram showing an example of the arrangement of a second control system;

FIG. 5 is a view showing an example of the arrangement of a neural network;

FIG. 6 is a graph showing the relationship between the stage deviation and the reward;

FIG. 7 is a flowchart showing a reward decision method;

FIG. 8 is a view showing an example of the arrangement of a neural network;

FIG. 9 is a view showing an example of the arrangement of a stage apparatus;

FIG. 10 is a view showing an example of the arrangement of an anti-vibration apparatus;

FIG. 11 is a block diagram showing an example of the arrangement of the control system of the anti-vibration apparatus;

FIG. 12 is a view showing an example of the arrangement of an imprint apparatus; and

FIG. 13 is a block diagram showing an example of the arrangement of the control system of the imprint apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

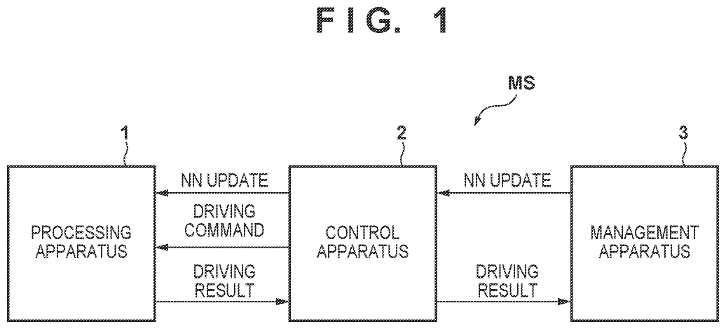

FIG. 1 shows the configuration of a manufacturing system MS (processing system) according to an embodiment. The manufacturing system MS can include, for example, a processing apparatus 1, a control apparatus 2 that controls the processing apparatus 1, and a management apparatus 3 that manages the processing apparatus 1 and the control apparatus 2. The processing apparatus 1 is an apparatus that executes processing on a processing target object, like a manufacturing apparatus, an inspection apparatus, a monitoring apparatus, or the like. The concept of the processing can include working, inspection, monitoring, and observation of a processing target object. Alternatively, the processing apparatus 1 may be an apparatus included in the above-described manufacturing apparatus or the like, such as a stage apparatus that moves while holding a substrate, or an anti-vibration apparatus that reduces vibrations transmitted to a target object such as a substrate. The first embodiment is an embodiment in which the processing apparatus 1 is a stage apparatus in a lithography apparatus. An embodiment in which the processing apparatus 1 is an anti-vibration apparatus will be described later as the fourth embodiment.

The processing apparatus 1 can include a controlled object (target object) and control the controlled object using a neural network for outputting a manipulated variable to the target object. A plurality of parameter values in the neural network can be decided by reinforcement learning. The control apparatus 2 can be configured to send a driving command to the processing apparatus 1 and receive a driving result or a control result from the processing apparatus 1. The management apparatus 3 can perform reinforcement learning of deciding a plurality of parameter values in the neural network of the processing apparatus 1. More specifically, the management apparatus 3 can decide the parameter values in the neural network by repeating an operation of sending a driving command to the processing apparatus 1 and receiving a driving result from the processing apparatus 1 while changing all or some of the parameter values in the neural network. The management apparatus 3 may be understood as a learning apparatus (learning unit).

All or some of the functions of the control apparatus 2 may be incorporated in the management apparatus 3. All or some of the functions of the control apparatus 2 may be incorporated in the processing apparatus 1. The processing apparatus 1, the control apparatus 2, and the management apparatus 3 may be formed physically integrally or separately. The processing apparatus 1 may be controlled by the control apparatus 2 as a whole, or may include components controlled by the control apparatus 2 and those not controlled by the control apparatus 2.

An example in which the manufacturing system MS is applied to a lithography apparatus will be explained below. The lithography apparatus generally includes a stage apparatus that moves while holding a substrate. Note that the lithography apparatus is an apparatus that forms a pattern on a substrate. The lithography apparatus is, for example, an exposure apparatus, an imprint apparatus, or an electron beam lithography apparatus. In the following description, the lithography apparatus is an imprint apparatus. The imprint apparatus is an apparatus that forms a pattern on a substrate by curing an imprint material supplied onto the substrate in a state in which a mold (original) is in contact with the imprint material.

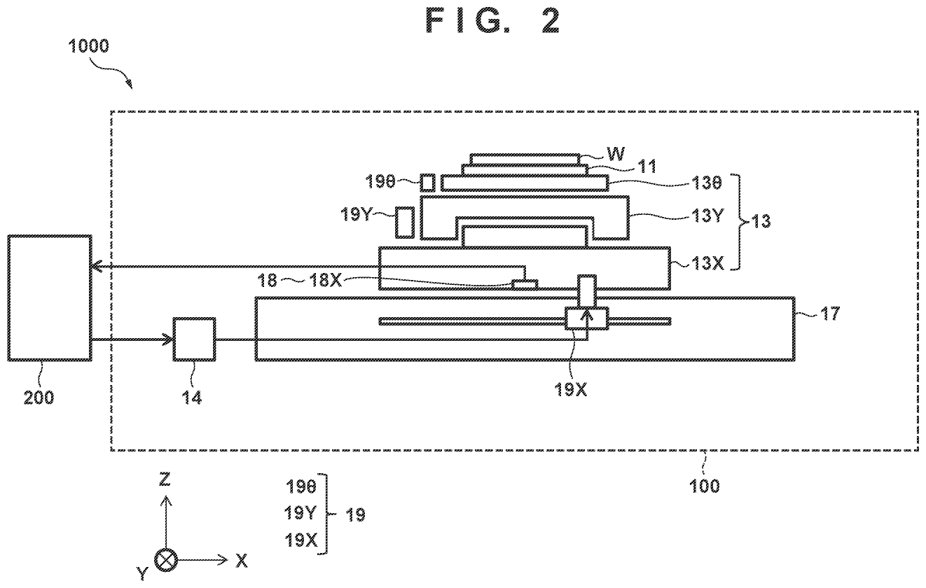

FIG. 2 is a view showing the arrangement of a stage apparatus 1000 employed in the imprint apparatus as the processing apparatus 1 according to the embodiment. In the specification and the drawings, directions will be indicated in an XYZ coordinate system in which the horizontal surface is set as the X-Y plane. The stage apparatus 1000 holds a substrate Won the holding surface of a stage device 13 such that the surface of the substrate W becomes parallel to the horizontal surface (X-Y plane). In the following description, directions orthogonal to each other in a plane along the holding surface of the stage device 13 are defined as the X- and Y-axes, and a direction perpendicular to the X- and Y-axes is defined as the Z-axis. In the following description, directions parallel to the X-, Y-, and Z-axes of the XYZ coordinate system are referred to as the X, Y, and Z directions, respectively, and a rotation direction about the Z-axis is referred to as the θ direction.

The stage apparatus 1000 includes a main body 100 and a control system 200. The substrate W serving as a controlled object is held by the stage device 13 via a substrate chuck 11. The stage device 13 moves the substrate W with strokes in the X and Y directions enough to perform pattern formation processing (imprint processing) in each shot region on the entire surface of the substrate W. The stage device 13 has strokes in the X and Y directions enough to move the substrate W to a replacement position where the substrate W is mounted/dismounted by a substrate replacement hand (not shown).

The stage device 13 can include an X stage 13X, a Y stage 13Y, and a θ stage 130. A linear motor 19 serving as a driver can include an X linear motor 19X, a Y linear motor 19Y, and a θ linear motor 190. The X linear motor 19X, the Y linear motor 19Y, and the θ linear motor 190 drive the X stage 13X, the Y stage 13Y, and the θ stage 130, respectively. The X stage 13X is guided freely moveably in the X direction using a static pressure guide, and receives a driving force in the X direction from the X linear motor 19X. On the X stage 13X, the Y stage 13Y can be moved in the Y direction by the static pressure guide and the Y linear motor 19Y. On the Y stage 13Y, the θ stage 130 can be moved in the θ direction by the static pressure guide and the θ linear motor 190. These linear motors are driven by a driver 14. The driver 14 supplies, to the linear motor 19, a current (electric energy) corresponding to a command value supplied from the control system 200. However, the arrangement of the stage device 13 is not limited to this. In particular, a higher-precision positioning stage is applicable to a stage apparatus in a lithography apparatus such as an imprint apparatus or an exposure apparatus. An example of the stage apparatus will be explained in the third embodiment.

A position measurement device 18 can include an X stage position measurement device 18X. The X stage position measurement device 18X measures a position of the X stage 13X in the X direction. The X stage position measurement device 18X is, for example, a linear encoder and can include a scale (not shown) arranged on a surface plate 17 on the stage apparatus 1000, and a head and a calculator on the X stage 13X. The position measurement device 18 can further include a linear encoder (not shown) that measures a position of the Y stage 13Y in the Y direction, and a linear encoder (not shown) that measures a position of the θ stage 130 in the θ direction. Instead of these linear encoders, a combination of an interferometer arranged on the main body structure of the imprint apparatus and a reflecting mirror arranged on the stage device 13 may be used to measure positions of the stage device 13 in the respective directions.

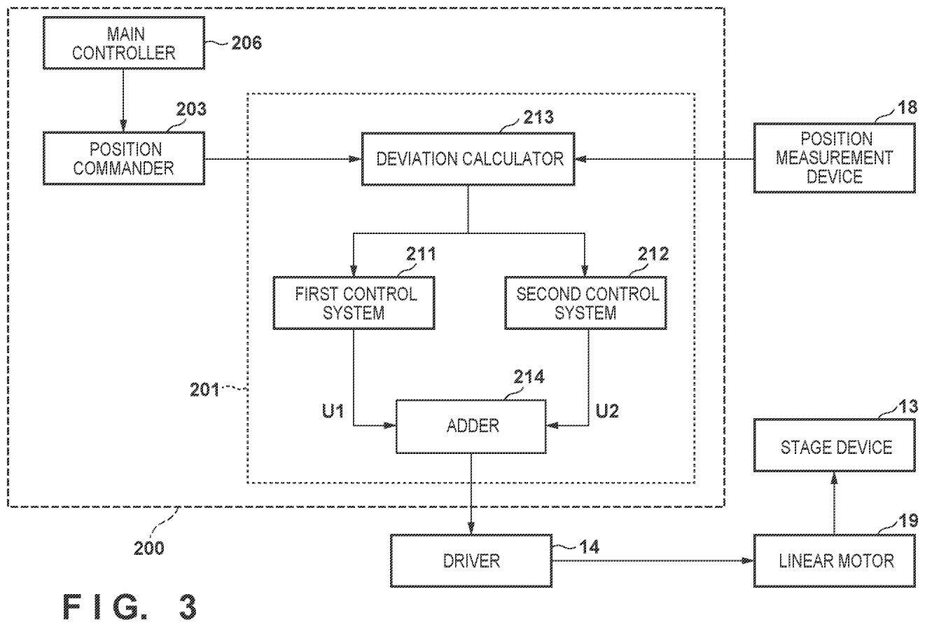

The control system 200 (controller) can control the position or state of the stage device 13 serving as a controlled object by using a neural network for which parameter values are decided by reinforcement learning. FIG. 3 is a block diagram showing the arrangement of the control system 200. The control system 200 is represented within a broken line. The control system 200 is formed from a digital computer to perform complicated calculation. Such a digital computer can include a processor such as a CPU or FPGA, and a storage device such as a memory. The control system 200 can include a main controller 206, a position commander 203, and a stage controller 201.

The main controller 206 has a role of sending commands to the stage controller 201 and other operating devices (not shown). The main controller 206 can be a controller that controls the overall imprint apparatus. The functions of the main controller 206 may be implemented in the control apparatus 2.

The stage position commander 203 obtains, from the main controller 206, coordinates representing the target position of the stage device 13, stores them, and sends the values to the stage controller 201. The position measurement device 18 measures the position (stage position) of the stage device 13 every sampling time, and sends the measured stage position to the stage controller 201.

The stage controller 201 can include a deviation calculator 213, a first control system 211, a second control system 212, and an adder 214. The deviation calculator 213 calculates a difference between a stage position (measurement value) received from the position measurement device 18 and a stage position (target value) received from the stage position commander 203. This difference is a control deviation, more particularly, a position deviation, and is referred to as a “stage deviation”. The stage deviation is sent to the first control system 211 and the second control system 212. The first control system 211 is a first compensator that generates a first command value based on the stage deviation. The first control system 211 can include a PID controller. The PID controller receives information about the stage deviation and outputs a first manipulated variable U1 (first command value) with respect to the stage device 13.

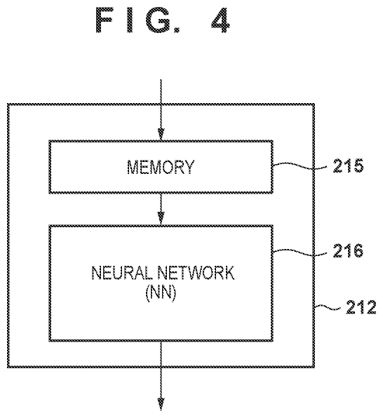

The second control system 212 is a second compensator that generates a second command value based on the stage deviation. FIG. 4 shows the arrangement of the second control system 212. The second control system 212 can include a memory 215 that saves the history of stage deviations, and a neural network (to be referred to as a “NN” hereinafter) 216. Based on an input stage deviation, the NN 216 outputs a value (second command value) equivalent to the correction value of the first manipulated variable U1 output from the first control system 211.

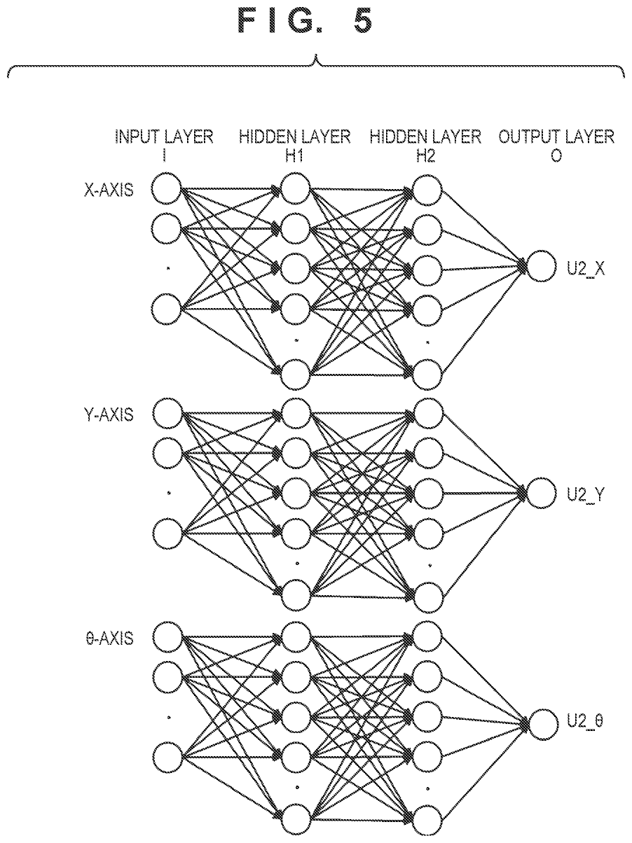

FIG. 5 shows an example of the arrangement of the NN 216. The NN 216 includes hidden layers H1 and H2 serving as intermediate layers between an input layer I and an output layer O. Stage deviations are input to the input layer I for N neighboring samples of the respective axes. In the hidden layer H1, calculation is performed on the input stage deviations of the respective axes. In the hidden layer H2, calculation is performed on values of the respective axes input from the hidden layer H1. That is, in the hidden layer H2, calculation is performed on stage deviations independently for the respective axes.

The NN 216 can independently output outputs U2_X, U2_Y, and U2_θ of the respective axes based on stage deviations of the respective axes. Note that the NN 216 shown in FIG. 5 is merely an example, and the NN is not limited to this. For example, it is also possible to connect stage deviations for N neighboring samples of the respective axes and then perform calculation of the hidden layer H1.

The parameters of the NN 216 can be adjusted by reinforcement learning executed by the management apparatus 3. The reinforcement learning is a kind of machine learning method, represents the goodness or badness of a behavior of a behavior entity by a numerical value serving as a reward, and decides the behavioral rule of the behavior entity so as to maximize a cumulative value R of rewards in the temporal direction. That is, the contents of the reward can be properly defined to obtain an excellent behavior entity capable of reaching a desired state as a result of accumulating behaviors toward the future.

The cumulative value R can be given by, for example:

R==Σₖγ^{k}·rₜ₊₁₊ₖ

where t is the time, r is the reward, γ is the discount rate of a future reward, and k is the time till the future reward. In the first embodiment, the behavior entity is the second control system 212.

Although the reinforcement learning method is not limited to a specific method, for example, Deep Q-Network (DQN) or Proximal Policy Optimization (PPO) is applicable. The NN 216 may be a network (policy network) that directly outputs an equivalence to the dimension of a command value, or a network (behavior value network) that calculates the value of a command value. In the case of the behavior value network, a selector configured to select a behavior that maximizes the value is added to the subsequent stage of the NN, and a command value selected by the selector serves as an output (second manipulated variable U2) of the second control system 212.

The adder 214 outputs a result (command value) of adding the first manipulated variable U1 (first command value) generated by the first control system 211, and the second manipulated variable U2 (second command value) generated by the second control system 212. The output from the adder 214 is converted into an analog signal through a D/A converter (not shown), and the signal is sent to the driver 14. In accordance with the value received from the adder 214, the driver 14 controls the value of a current flowing through the coil of the linear motor 19. The thrust of the linear motor 19 is proportional to a current flowing through the coil, and a force corresponding to the sum of the output values of the first control system 211 and second control system 212 is applied to the stage device 13.

In this arrangement, the first control system 211 mainly has charge of a position feedback control system, and the second control system 212 has a function of further reducing a stage deviation that cannot be completely compensated by the first control system 211. The stage deviation can be decreased much more than by a control system including only the first control system 211. The first control system 211 can be, for example, a PID compensator, but may be another compensator. The first control system 211 is not always necessary, and only the second control system 212 may generate a command value supplied to the driver 14.

Reinforcement learning is performed by evaluating a reward obtained from the result of controlling a target object by the control system 200. The reward of reinforcement learning will be explained. For example, a reward r of reinforcement learning is given by:

r=Gx·rx+Gr·ry+Gθ·rθ (2)

where rx, ry, and rθ are the rewards regarding the X-, Y-, and θ-axes, respectively, and Gx, Gy, and Gθ are the weights of the rewards of the X-, Y-, and θ-axes, respectively.

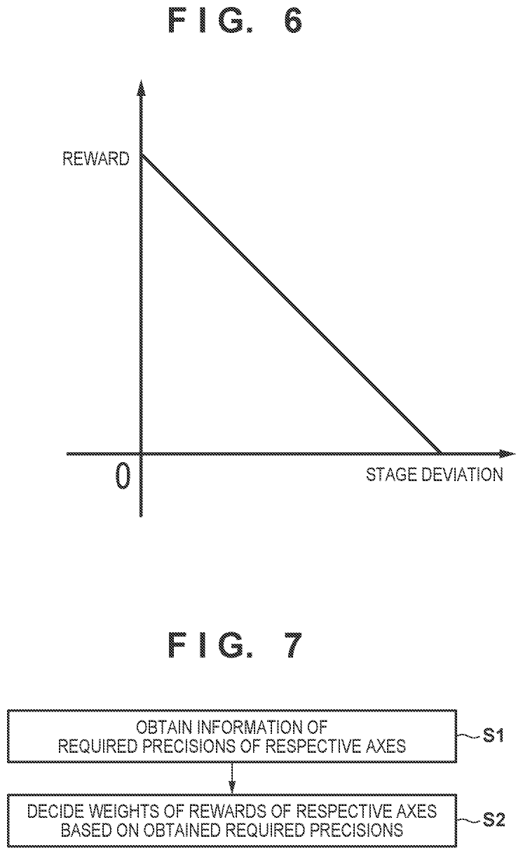

In this manner, the reward r of reinforcement learning is represented by the weighted sum of rewards of the respective axes. As shown in FIG. 6, the rewards rx, ry, and re of the respective axes can be decided in accordance with the magnitudes of stage deviations of the respective axes. In FIG. 6, as the stage deviation is smaller, a larger reward is obtained.

The weights Gx, Gy, and Gθ on the rewards of the respective axes are decided in accordance with the required precisions of the respective axes. For example, when the required precision of the X-axis is stricter than those of the Y- and θ-axes, the value of the weight Gx is set to be larger than those of the weights Gy and Gθ. That is, equation (2) is so set as to obtain a larger reward r if stage deviations of the respective axes are reduced in accordance with the required precisions.

As the management method of the management apparatus 3, a method of deciding the weights Gx, Gy, and Gθ of the rewards of the respective axes will be explained with reference to the flowchart of FIG. 7. In step S1, the management apparatus 3 obtains information of the required precisions of the respective axes. The required precisions of the respective axes can be precision information input by the user as a requirement from the user. Then, in step S2, the management apparatus 3 decides the weights Gx, Gy, and Gθ of the rewards of the respective axes based on the obtained required precisions. For example, when the required precision of the X-axis is 3 nm and that of the Y-axis is 6 nm, the weights Gx and Gy are decided to be 2 and 1, respectively. Such a weight can be obtained by, for example, looking up a table describing a correspondence between the required precision and the weight that is obtained in advance. Alternatively, the weight may be obtained by obtaining in advance a function (expression) that uses a required precision as a variable and represents a weight, and applying an obtained required precision to the function. The management apparatus 3 calculates the reward of reinforcement learning using decided weights of the respective axes. Rewards regarding the respective drive axes are relatively adjusted in accordance with obtained required precisions corresponding to the respective drive axes.

As described above, according to the embodiment, the management apparatus 3 (learning unit) performs reinforcement learning of the NN 216 by evaluating a reward obtained from the result of controlling the stage device 13 by the control system 200. The management apparatus 3 can adjust the NN 216 in accordance with a requirement from the user so as to satisfy the requirement. For example, according to the embodiment, rewards corresponding to required precisions for the respective drive axes are relatively adjusted by weighting the rewards of the respective axes. Hence, stage deviations of the respective axes can be efficiently reduced at limited calculation cost.

The required precisions of the respective axes may be not only stage deviations of the respective axes but also times till stage deviations of the respective axes settle at predetermined magnitudes. In this case, the rewards of the respective axes are decided in accordance with the settling times of the respective axes. The stage deviations of the respective axes are used as inputs of the NN 216 in the above-described example, but other information regarding the respective axes may also be used.

### Second Embodiment

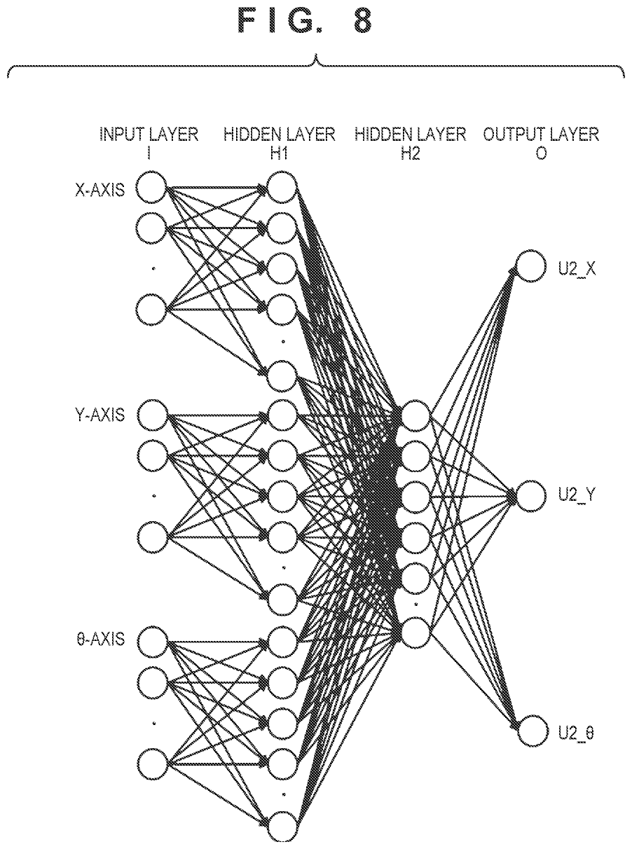

In the second embodiment, a NN of a form different from the NN 216 (FIG. 5) in the first embodiment will be exemplified. FIG. 8 shows an example of the arrangement of a NN 216 according to the second embodiment. The NN 216 includes hidden layers H1 and H2 serving as intermediate layers between an input layer I and an output layer O. Stage deviations are input to the input layer I for N neighboring samples of the respective axes. In the hidden layer H1, calculation is performed on input stage deviations of the respective axes. In the hidden layer H2, calculation is performed on values of all the axes input from the hidden layer H1. In the hidden layer H2 according to the first embodiment (FIG. 5), calculation is performed on stage deviations independently for the respective axes. In the hidden layer H2 according to the second embodiment, calculation is performed in consideration of the stage deviations of all the axes.

The NN 216 can output outputs U2_X, U2_Y, and U2_θ of the respective axes in consideration of the magnitudes of stage deviations of all the axes. For example, when stage deviations between the axes are correlated, the stage deviations of the respective axes can be reduced more efficiently and effectively by using the NN 216 according to the second embodiment than by using the NN 216 according to the first embodiment. Note that the NN 216 shown in FIG. 8 is merely an example, and the NN is not limited to this form. For example, it is also possible to connect stage deviations for N neighboring samples of the respective axes and then perform calculation in the hidden layer H1.

### Third Embodiment

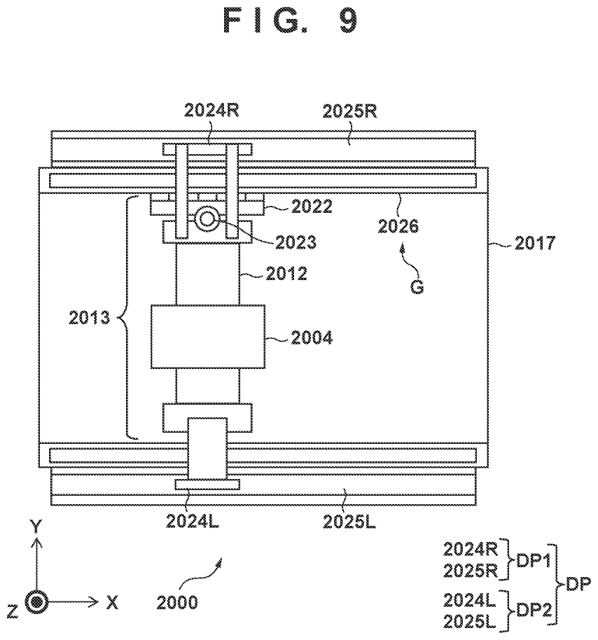

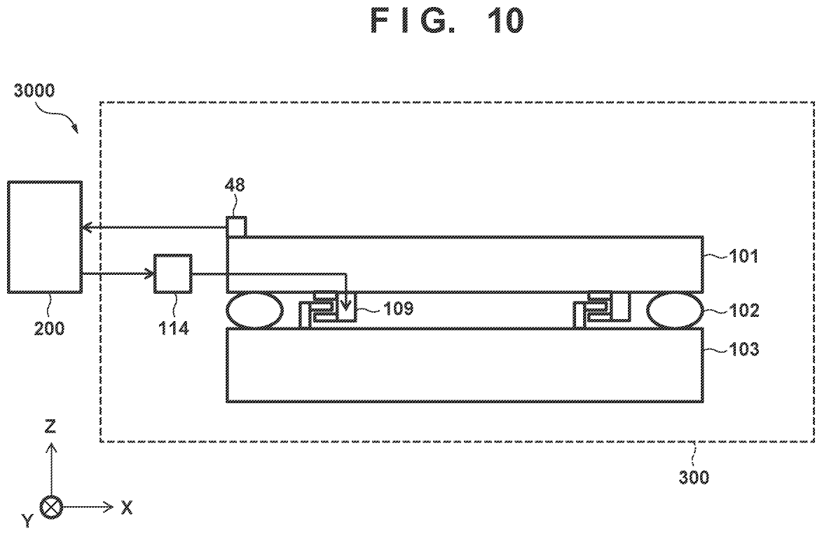

In the third embodiment, a stage apparatus of a form different from the stage apparatus 1000 (FIG. 2) in the first embodiment will be exemplified. FIG. 9 is a view showing the arrangement of a stage apparatus 2000 according to the third embodiment. The stage apparatus 2000 is a positioning apparatus that moves a movable device serving as a target object on a surface parallel to the first and second directions orthogonal to each other.

The stage apparatus 2000 is configured to move a stage device 2013 on a surface plate 2017 by a driver DP. The stage apparatus 2000 includes a single guide G as a guide that restrains a position of the stage device 2013 in the Y direction. This means that the stage apparatus 2000 includes only one guide G as a guide that restrains a position of the stage device 2013 in the Y direction. The guide G has a guide surface 2026 parallel to the X direction, and the guide surface 2026 is a surface perpendicular to the surface plate 2017.

The stage device 2013 includes an X movable member (first movable member) 2022, an X beam (second movable member) 2012, and a Y slider (third movable member) 2004. The X movable member 2022 is movable in the X direction (first direction) while guided by the guide G. The X beam 2012 is supported and guided by the surface plate 2017 via a hydrostatic bearing formed from a hydrostatic pad. The X beam 2012 has first and second ends, the first end is connected to the X movable member 2022 via a rotary bearing 2023, and the X beam 2012 moves on the surface plate 2017. The Y slider 2004 is movable within a predetermined range between the first and second ends by a driver (not shown) while guided by the X beam 2012.

The driver DP includes a first driver DP1 that drives the first end (end on a side in the +Y direction) of the X beam (second movable member) 2012 in the X direction (first direction), and a second driver DP2 that drives the second end (end on a side in the −Y direction) of the X beam 2012 in the X direction.

The first driver DP1 can be formed from, for example, a linear motor. More specifically, the first driver DP1 can be formed from a linear motor including a movable element (first movable element) 2024R and a stator (first stator) 2025R. The movable element 2024R can be connected to the first end of the X beam 2012, and the stator 2025R can be connected to the side surface of the surface plate 2017. The guide surface 2026 of the guide G can be arranged between the stator 2025R and the X movable member 2022.

The second driver DP2 can be formed from, for example, a linear motor. More specifically, the second driver DP2 can be formed from a linear motor including a movable element (second movable element) 2024L and a stator (second stator) 2025L. The movable element 2024L can be connected to the second end of the X beam 2012, and the stator 2025L can be connected to the side surface of the surface plate 2017. A guide that restrains a position of the second end in the Y direction does not exist on the side of the second end of the X beam 2012.

In the stage apparatus 1000 according to the first embodiment, the X stage 13X, the Y stage 13Y, and the θ stage 130 can be independently positioned to position the substrate W on the stage device 13. In the stage apparatus 2000 according to the third embodiment, however, the respective axes interfere with each other. To position, for example, a substrate on the stage device 2013 in regard to the X-axis, not only the X position of the X movable member 2022, but also the angle θ of the X beam and the Y position of the Y slider need to be controlled simultaneously. When the respective axes interfere with each other as in the stage apparatus 2000, the NN 216 advantageously includes a hidden layer H2 in which calculation is performed in consideration of the stage deviations of all the axes, as shown in FIG. 8, in order to effectively reduce stage deviations of the respective axes at limited calculation cost.

### Fourth Embodiment

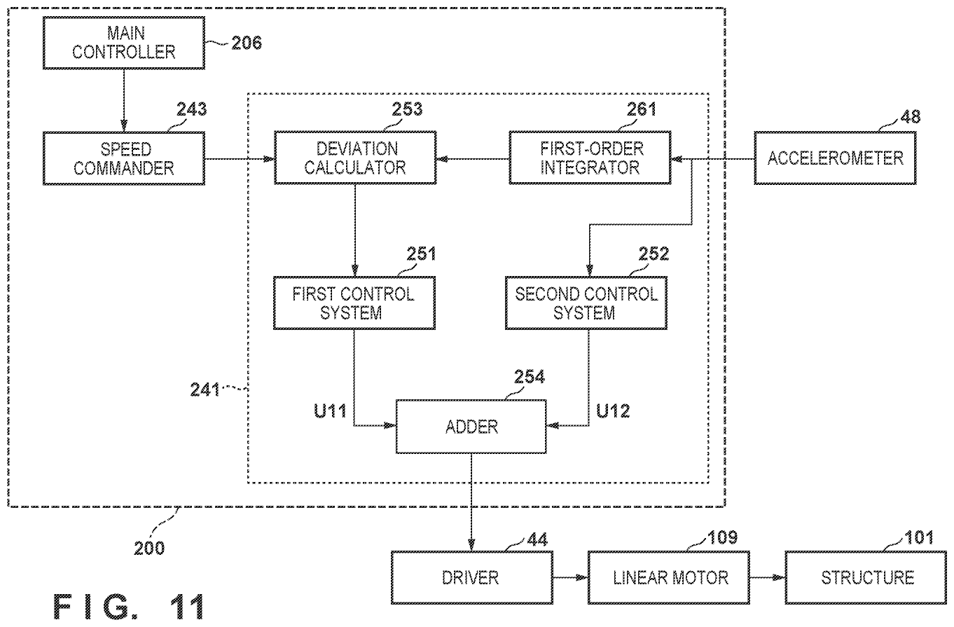

The fourth embodiment is an embodiment of an anti-vibration apparatus that reduces vibrations transmitted to a target object. FIG. 10 is a view showing an example of the arrangement of an anti-vibration apparatus 3000 according to the fourth embodiment. The anti-vibration apparatus 3000 includes a main body 300 and a control system 200. On the main body 300, a main body 100 of a stage apparatus 1000 as shown in FIG. 2 can be mounted. In the main body 300, a main body structure (anti-vibration table) 101 is installed on a floor 103 via a three- or four-legged anti-vibration mechanism 102 that uses an air spring or the like. A linear motor 109 serving as a driver is attached to the main body structure 101. The linear motor 109 is configured to apply a force to the main body structure 101 along six axes. An accelerometer 48 is arranged in the main body structure 101. The accelerometer 48 is configured to measure an acceleration of the main body structure 101 along the six axes. Information about the acceleration of the main body structure 101 measured by the accelerometer 48 is sent to the control system 200.

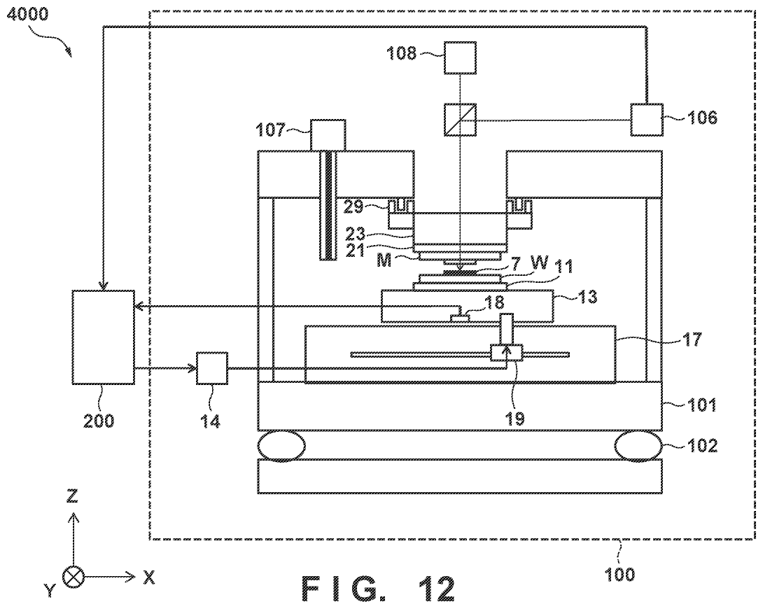

FIG. 11 is a block diagram showing the arrangement of the control system 200. The control system 200 is represented within a broken line. The control system 200 can include a main controller 206, a speed commander 243, and an anti-vibration controller 241.

The speed commander 243 sends the target speed of the main body structure 101 from the main controller 206 to the anti-vibration controller 241. The anti-vibration controller 241 can include a deviation calculator 253, a first-order integrator 261, a first control system 251, a second control system 252, and an adder 254. The first-order integrator 261 obtains the speed of the main body structure 101 by integrating the acceleration of the main body structure 101 received from the accelerometer 48. The deviation calculator 253 calculates a difference (control deviation; to be referred to as a “speed deviation” hereinafter) between a speed of the main body structure 101 obtained by the first-order integrator 261 and a speed (target value) of the main body structure 101 received from the speed commander 243. The speed deviation is sent to the first control system 251.

The first control system 251 is a first compensator that generates a first command value based on the speed deviation. For example, the first control system 251 can include a PID controller. The PID controller receives information about the speed deviation and outputs a first manipulated variable U11 (first command value) with respect to the main body structure 101.

Information about the acceleration of the main body structure 101 obtained by the accelerometer 48 is also sent to the second control system 252. The second control system 252 is a second compensator that generates a second manipulated variable U12 (second command value) based on the acceleration of the main body structure 101 (anti-vibration table) measured by the accelerometer 48. The second control system 252 includes a NN, and outputs the second manipulated variable U12 based on the acceleration of the main body structure 101 received from the accelerometer 48. Before sent to the second control system 252, the acceleration of the main body structure 101 may be processed by a cut-off filter, a differentiator, an integrator, or the like that removes a predetermined frequency component. The cut-off filter can be a low-pass filter, a high-pass filter, a bandpass filter, or the like.

The adder 254 outputs a result (command value) of adding the first manipulated variable U11 (first command value) generated by the first control system 251, and the second manipulated variable U12 (second command value) generated by the second control system 252. The output from the adder 254 is converted into an analog signal through a D/A converter (not shown), and the signal is sent to a driver 44. In accordance with the value received from the adder 254, the driver 44 controls the value of a current flowing through the coil of the linear motor 109. Since the thrust of the linear motor 109 is proportional to a current flowing through the coil, a force corresponding to the sum of the output values of the first control system 251 and second control system 252 is applied to the main body structure 101.

In this arrangement, the first control system 251 mainly has charge of the speed feedback control system, and the second control system 252 has a function of reducing the acceleration of the main body structure 101 that cannot be completely compensated by the first control system 251. Vibrations of the main body structure 101 can be reduced much more than by a control system including only the first control system 251. The first control system 251 can be, for example, a PID compensator, but may be another compensator. The first control system 251 is not always necessary, and only the second control system 252 may generate a command value supplied to the driver 44.

The parameters of the NN of the second control system 252 are adjusted by reinforcement learning. Similar to the first embodiment, the reward of reinforcement learning is obtained by weighting and adding rewards of the respective axes using weights corresponding to the required precisions (accelerations or speeds) of vibrations of the respective axes of the main body structure 101. As a result, vibrations of the respective axes can be reduced in accordance with the required precisions of the respective axes at limited calculation cost.

The speed of the main body structure 101 is obtained by integrating, by the first-order integrator 261, the acceleration of the main body structure 101 received from the accelerometer 48 in the above-described example, but the speed of the main body structure 101 may be directly measured using a speedometer. In this case, the acceleration of the main body structure 101 may be obtained by performing first-order differentiation of a measurement value of the speedometer. Although accelerations of the respective axes are used as inputs to the NN 216 in the above-described example, other information about the respective axes may also be used.

### Fifth Embodiment

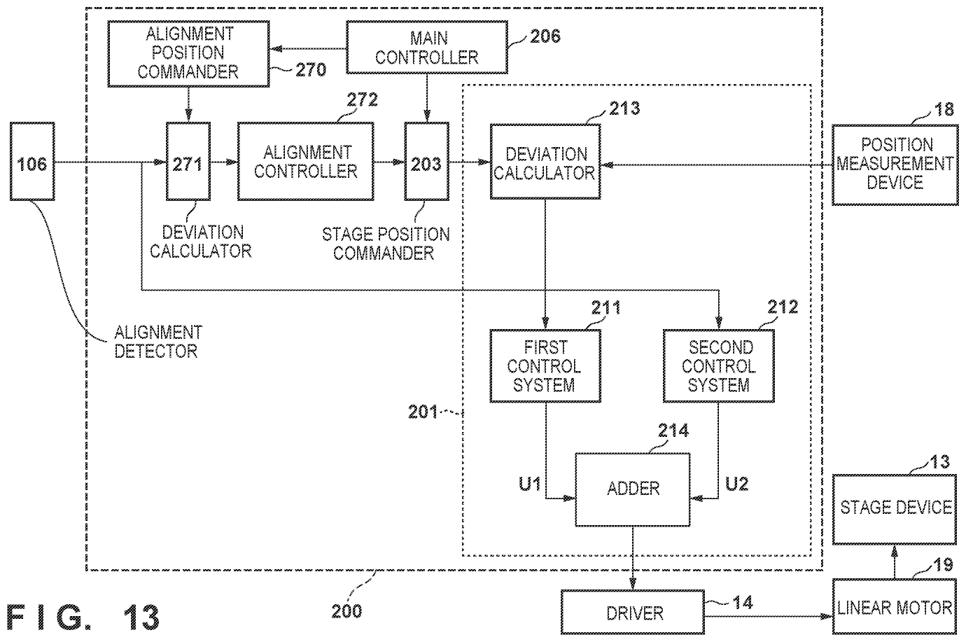

In the fifth embodiment, an imprint apparatus 4000 will be explained as an aspect of a molding apparatus to which the present invention is applied. FIG. 12 is a view showing the arrangement of the imprint apparatus 4000 according to the fifth embodiment. The imprint apparatus 4000 can include the stage apparatus described in any one of the first to third embodiments. Further, the imprint apparatus 4000 can also include the anti-vibration apparatus described in the fourth embodiment.

The imprint apparatus 4000 includes a formation device that brings an imprint material 7 supplied onto a substrate W into contact with a mold M, and applies curing energy to the imprint material 7, thereby forming a pattern of the cured material to which the concave-convex pattern of the mold M is transferred. For example, the imprint apparatus 4000 supplies the imprint material 7 onto the substrate W, and cures the imprint material 7 in a state in which the mold M having a concave-convex pattern contacts the imprint material 7 on the substrate W. Then, the imprint apparatus 4000 widens the interval between the mold M and the substrate W and peels (releases) the mold M from the cured imprint material 7, thereby transferring the pattern of the mold M to the imprint material 7 on the substrate W. The series of processes are called imprint processing, and the imprint processing is performed for each of shot regions on the substrate W. That is, when imprint processing is performed for each of shot regions on one substrate W, it is repeated by the number of shot regions on the substrate W.

The imprint material 7 can be a photo-curing resin. The imprint material 7 of this type is supplied from a dispenser 107 to the position of a shot region on the substrate W. More specifically, a stage device 13 positions, immediately below the dispenser 107, a position on the substrate W where the imprint material 7 is to be supplied. Then, the stage device 13 positions, immediately below the mold M, the position on the substrate W where the imprint material 7 is to be supplied. The mold M is held by an imprint head 23. The imprint head 23 can move the mold M in the Z direction by an actuator 29. The mold M stands by at a position above the substrate W in the Z direction until the position of the shot region of the substrate W moves to immediately below the mold M. When the shot position of the substrate W is positioned immediately below the mold M, the imprint head 23 moves down the mold M and brings the pattern of the mold M into contact with the imprint material 7. When manufacturing a semiconductor device or the like by the imprint apparatus, positioning (alignment) with a preceding layer is important in transferring the pattern of the mold M to the imprint material 7 on the substrate W. An alignment detector 106 optically detects alignment marks (not shown) provided on both the substrate W and the mold M, performs image processing, and detects a misalignment (misalignment between the substrate W and the mold M) between the alignment marks in the X and Y directions. The misalignment information is sent to a control system 200, and alignment is performed by correcting the X and Y positions and θ angle of the stage device 13. Upon completion of the alignment, an illumination system 108 irradiates the imprint material 7 with exposure light, curing the imprint material 7. After curing the imprint material 7, the imprint head 23 moves up the mold M, releasing the mold M from the imprint material 7 on the substrate W. By the series of processes, a pattern corresponding to the pattern engraved on the mold M is transferred to the imprint material 7 on the substrate W. Similarly, imprint processing is sequentially performed on the remaining shot regions. Upon completion of imprint processing on all the shot regions on one substrate, the stage device 13 moves to a substrate replacement position. Then, a substrate replacement hand (not shown) recovers the substrate having undergone imprint processing, and supplies a next new substrate.

FIG. 13 is a block diagram showing the arrangement of the control system 200 of the imprint apparatus 4000. The alignment detector 106 measures a misalignment between the substrate W and the mold M, and sends information of the measured misalignment between the substrate W and the mold M to the control system 200. An alignment position commander 270 obtains the target value of the misalignment between the substrate W and the mold M from the main controller 206, and stores it. A deviation calculator 271 calculates a difference (control deviation; to be referred to as an “alignment error” hereinafter) between the misalignment received from the alignment detector 106 and the target value of the misalignment received from the alignment position commander 270. The alignment error is sent to an alignment controller 272. The alignment controller 272 uses, for example, a PI controller, receives the alignment error from the deviation calculator 271, and outputs a correction value for correcting the target value of the stage position sent from a position commander 203.

In the fifth embodiment, information of the misalignment between the substrate W and the mold M by the alignment detector 106 is sent to a second control system 212. Similar to the first embodiment, the second control system 212 includes a NN 216. Based on the input information of the misalignment between the substrate W and the mold M by the alignment detector 106, the NN 216 outputs a value equivalent to the correction value of the first manipulated variable U1 of a first control system 211. In the first embodiment, the second control system 212 has a function of further reducing a stage deviation that cannot be completely compensated by the first control system 211. In the fifth embodiment, the second control system 212 has a function of reducing a misalignment between the substrate W and the mold M that cannot be completely compensated by the first control system 211. Before sent to the second control system 212, the information of the misalignment between the substrate W and the mold M by the alignment detector 106 may pass through a cut-off filter (not shown) that removes a predetermined frequency component. The cut-off filter can be a low-pass filter, a high-pass filter, a bandpass filter, or the like.

Pieces of information of misalignments between the substrate W and the mold M by the alignment detector 106 for the respective axes are used as inputs to the NN 216 in the fifth embodiment, but other information about the respective axes may also be used.

### Sixth Embodiment

In the above-described fifth embodiment, the imprint apparatus that brings an imprint material and a mold into contact with each other to transfer the pattern of the mold to the imprint material has been explained as an aspect of a molding apparatus. However, as another aspect of the molding apparatus, the present invention can also be applied to a planarization apparatus that brings a moldable material (composition) on a substrate and a member (mold) having a flat surface into contact with each other, forming a planarized film from the composition on the substrate.

An underlying pattern on a substrate has a concave-convex profile derived from a pattern formed in a previous step. In particular, the advance of multilayered structures of recent memory elements has implemented process substrates having a step of about 100 nm. A step derived from the moderate undulation of the entire substrate can be corrected by the focus tracking function of a scan exposure apparatus used in the photo process. However, fine concave/convex portions having a pitch small enough to fall within the exposure slit area of the exposure apparatus may fall outside the Depth Of Focus (DOF) of the exposure apparatus. As a conventional method of planarizing the underlying pattern of a substrate, a method of forming a planarized layer, such as Spin On Carbon (SOC) or Chemical Mechanical Polishing (CMP), is used. However, the conventional technique undesirably cannot obtain sufficient planarization performance, and the concave/convex difference of the underlayer by multilayer formation tends to increase.

To solve this problem, a planarization apparatus that planarizes a substrate using the above-mentioned imprint technique is being examined. The planarization apparatus brings the flat surface of a member or a member (flat template) having no pattern into contact with an uncured composition supplied in advance to a substrate, and performs local planarization of the substrate surface. Then, the planarization apparatus cures the composition in the state in which the composition and the flat template contact each other, and separates the flat template from the cured composition. As a result, the planarized layer is formed on the substrate. The planarization apparatus using the imprint technique drops a composition by an amount corresponding to a step of a substrate, and is expected to improve the planarization precision in comparison with an existing method.

The planarization apparatus forms a planarized film at once on the entire surface of a substrate. At this time, the embodiment can be applied to prevent the composition from overflowing from the substrate or reduce non-filling of the substrate.

Further, the present invention is also applicable to a measurement apparatus and a processing apparatus, in addition to the lithography apparatus including the molding apparatus. The measurement apparatus includes a feedback control apparatus to control the position of a target object, and a measurement device that measures the object whose position is controlled by the feedback control apparatus. The measurement device is, for example, a contact probe or a noncontact interferometer. The processing apparatus includes the above-mentioned feedback control apparatus to control the position of a target object, and a processing device that processes the object whose position is controlled by the feedback control apparatus. The processing device is, for example, a tool or a laser.

<Embodiment of Article Manufacturing Method>

An article manufacturing method according to an embodiment of the present invention is suitable for manufacturing an article, for example, a microdevice such as a semiconductor device or an element having a fine structure. The article manufacturing method according to the embodiment includes a transfer step of transferring the pattern of an original onto a substrate using the above-described lithography apparatus (an exposure apparatus, an imprint apparatus, a drawing apparatus, or the like), and a processing step of processing the substrate having undergone the transfer step. The manufacturing method also includes other known processes (for example, oxidation, deposition, vapor deposition, doping, planarization, etching, resist removal, dicing, bonding, and packaging). The article manufacturing method according to the embodiment is advantageous in at least one of the performance, quality, productivity, and production cost of the article, as compared to conventional methods.

A method of manufacturing an article (a semiconductor IC element, a liquid crystal display element, a color filter, a MEMS, or the like) by using the above-described planarization apparatus will be described next. The manufacturing method includes, by using the above-described planarization apparatus, a step of planarizing a composition by bringing the composition arranged on a substrate (a wafer, a glass substrate, or the like) and a mold into contact with each other, a step of curing the composition, and a step of separating the composition and the mold from each other. With this, a planarized film is formed on the substrate. Then, processing such as pattern formation using a lithography apparatus is performed on the substrate with the planarized film formed thereon, and the processed substrate is processed in other known processing steps to manufacture an article. Other known steps include etching, resist removal, dicing, bonding, packaging, and the like. This manufacturing method can manufacture an article with higher quality than conventional methods.

<Others>

A physical quantity used for control by a control apparatus is not limited to those used in the following embodiments, and the type of physical quantity is arbitrary as long as feedback control is possible. The physical quantity is, for example, the displacements of an object in the rectilinear propagation and rotational directions, the speed or acceleration of the object, or the flow rate, flow velocity, or pressure of a gas or fluid. The physical quantity is, for example, the liquid level of a fluid, the temperature of an object, gas, or liquid, the current, voltage, or charges of an electrical circuit or the like. Also, the physical quantity is, for example, a magnetic flux or magnetic flux density in a magnetic field, or a sound pressure in a sound field. Such a physical quantity is measured by a detection device using a known detector (sensor), and the measurement value is input to the control apparatus. A driver is an active element that applies a change to a physical quantity serving as a controlled target. When the controlled target is the position, speed, or acceleration of an object, motors, a piezo element, or the like is used. When the controlled target is a gas, a fluid, or the like, a pump, a valve, or the like is used. When the controlled target is an electrical system, a driver or the like that manipulates a current or a voltage is used.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-067816, filed Apr. 15, 2022, which is hereby incorporated by reference herein in its entirety.

What is claimed is:

1. A management apparatus for managing a processing apparatus including a driver configured to drive a target object in regard to a plurality of drive axes, and a controller configured to control the driver using a neural network for which a parameter for outputting a manipulated variable to the target object is decided by reinforcement learning, the management apparatus comprising:
a learning unit configured to decide the parameter of the neural network by reinforcement learning,
wherein the learning unit performs the reinforcement learning by evaluating a reward obtained from a control result of the target object by the controller, and relatively adjusts rewards regarding the respective drive axes in accordance with required precisions for the respective drive axes.

2. The management apparatus according to claim 1, wherein the reward evaluated in the reinforcement learning is represented by a weighted sum of the rewards regarding the respective drive axes, and
the learning unit decides respective weights in the weighted sum in accordance with the required precisions for the respective drive axes.

3. The management apparatus according to claim 2, wherein the learning unit obtains the required precisions for the respective drive axes, and decides weights corresponding to the obtained required precisions based on a correspondence between the required precision and the weight that is obtained in advance.

4. A processing system comprising:
a processing apparatus including a driver configured to drive a target object in regard to a plurality of drive axes, and a controller configured to control the driver using a neural network for which a parameter for outputting a manipulated variable to the target object is decided by reinforcement learning; and
a learning apparatus configured to decide the parameter of the neural network by reinforcement learning,
wherein the learning apparatus performs the reinforcement learning by evaluating a reward obtained from a control result of the target object by the controller, and relatively adjusts rewards regarding the respective drive axes in accordance with required precisions for the respective drive axes.

5. The system according to claim 4, wherein the reward evaluated in the reinforcement learning is represented by a weighted sum of the rewards regarding the respective drive axes, and
the learning apparatus decides respective weights in the weighted sum in accordance with the required precisions for the respective drive axes.

6. The system according to claim 5, wherein the learning apparatus obtains the required precisions for the respective drive axes, and decides weights corresponding to the obtained required precisions based on a correspondence between the required precision and the weight that is obtained in advance.

7. The system according to claim 4, wherein the controller is configured to generate a command value to the driver based on a control deviation,
the controller includes:
a first compensator configured to generate a first command value based on the control deviation;
a second compensator configured to generate a second command value based on the control deviation; and
an adder configured to obtain the command value by adding the first command value and the second command value, and
the neural network is included in the second compensator.

8. The system according to claim 4, wherein the processing apparatus is a positioning apparatus configured to move a movable device serving as the target object on a surface parallel to a first direction and a second direction that are orthogonal to each other.

9. The system according to claim 8, wherein the positioning apparatus includes a single guide serving as a guide that restrains a position of the movable device in the second direction,
the movable device includes:
a first movable device movable in the first direction while guided by the guide;
a second movable device including a first end and a second end, the first end being connected to the first movable device via a rotation bearing and moving on the surface; and
a third movable device movable within a predetermined range between the first end and the second end while guided by the second movable device, and
the driver includes:
a first driver configured to drive the first end of the second movable device in the first direction; and
a second driver configured to drive the second end of the second movable device in the first direction.

10. The system according to claim 4, wherein the processing apparatus is an anti-vibration apparatus configured to reduce vibrations transmitted to a target object.

11. The system according to claim 10, wherein the anti-vibration apparatus includes an anti-vibration table on which the target object is mounted, and an accelerometer arranged on the anti-vibration table,
the driver is configured to drive the anti-vibration table,
the controller is configured to generate a command value to the driver based on a control deviation,
the controller includes:
a first compensator configured to generate a first command value based on a speed deviation;
a second compensator configured to generate a second command value based on an acceleration of the anti-vibration table measured by the accelerometer; and
an adder configured to obtain the command value by adding the first command value and the second command value, and
the neural network is included in the second compensator.

12. The system according to claim 4, wherein the processing apparatus is a lithography apparatus configured to perform processing of transferring a pattern of an original to a substrate serving as the target object.

13. The system according to claim 12, wherein the lithography apparatus includes a stage device on which the substrate serving as the target object is mounted, an alignment detector configured to measure a misalignment between the original and the substrate, and a position measurement device configured to measure a position of the stage device,
the driver is configured to drive the stage device,
the controller is configured to generate a command value to the driver based on a control deviation,
the controller includes:
a first compensator configured to generate a first command value to the driver based on a position deviation serving as a difference between a target value and a measurement value obtained by the position measurement device;
a second compensator configured to generate a second command value based on the misalignment measured by the alignment detector; and
an adder configured to obtain the command value by adding the first command value and the second command value, and
the neural network is included in the second compensator.

14. A management method of managing a processing apparatus including a driver configured to drive a target object in regard to a plurality of drive axes, and a controller configured to control the driver using a neural network for which a parameter for outputting a manipulated variable to the target object is decided by reinforcement learning, the method comprising:
deciding the parameter of the neural network by reinforcement learning including evaluation of a reward obtained from a control result of the target object by the controller,
wherein the deciding includes:
obtaining required precisions for the respective drive axes; and
relatively adjusting rewards regarding the respective drive axes in accordance with the obtained required precisions for the respective drive axes.

15. An article manufacturing method comprising:
transferring a pattern of an original to a substrate by using the lithography apparatus in the processing system defined in claim 13; and
processing the substrate having undergone the transferring,
wherein an article is obtained from the substrate having undergone the processing.

16. A management apparatus for managing a processing apparatus including a controller configured to control a target object using a neural network, the apparatus comprising:
a learning unit configured to perform reinforcement learning of the neural network by evaluating a reward obtained from a control result of the target object by the controller,
wherein the learning unit adjusts, in accordance with a requirement from a user, the neural network to satisfy the requirement.
